(19) United States
(12) Patent Application Publication
(10) Pub. No.: US 2026/0150666 A1
(43) Pub. Date: May 28, 2026

(54) SEMICONDUCTOR DEVICE

(71) Applicant: Mitsubishi Electric Corporation, Tokyo (JP)

(72) Inventor: Tomohito KUDO, Tokyo (JP)

(73) Assignee: Mitsubishi Electric Corporation, Tokyo (JP)

(21) Appl. No.: 19/334,313

(22) Filed: Sep. 19, 2025

(30) Foreign Application Priority Data
Nov. 25, 2024 (JP) 2024-204711

(51) Int. Cl. H01L 23/34; G01K 7/01

(52) U.S. Cl. CPC H10W 40/00; G01K 7/015

(57) ABSTRACT

A semiconductor device includes a semiconductor substrate, a temperature sensing diode formed on the semiconductor substrate, an anode wiring connected to an anode portion of the temperature sensing diode, and a cathode wiring connected to a cathode portion of the temperature sensing diode. One of the anode wiring and the cathode wiring is disposed to overlap the other.

### BACKGROUND

### Technical Field

The present disclosure relates to a semiconductor device, and particularly relates to a semiconductor device including a temperature sensing diode.

### Description of the Background Art

In order to monitor a temperature of a semiconductor element, a semiconductor device mounted with a diode having electric characteristics depending on a temperature is known. Hereinafter, a diode for temperature monitoring of a semiconductor element will be referred to as a “temperature sensing diode”. The temperature sensing diode is preferably disposed in a central portion of an active region where the semiconductor element is formed in order to increase measurement accuracy of the temperature of the semiconductor element. However, if a region where the temperature sensing diode is disposed is secured in the active region, an effective area of the active region may be reduced, which may lead to deterioration of characteristics of the semiconductor device.

For example, WO 2023/053439 discloses a technique of embedding a temperature sensing diode in a trench formed in a semiconductor substrate to reduce an area and increase sensitivity of the temperature sensing diode.

In order to dispose the temperature sensing diode in the central portion of the active region, it is necessary to secure not only a region where the temperature sensing diode is disposed but also a region where a wiring connecting the temperature sensing diode to a temperature sense terminal disposed outside the active region is disposed within the active region. Thus, reduction in an area of the wiring between the temperature sensing diode and the temperature sense terminal is also an important problem.

### SUMMARY

An object of the present disclosure is to provide a semiconductor device capable of reducing an area of a wiring between a temperature sensing diode and a temperature sense terminal.

A semiconductor device according to the present disclosure includes a semiconductor substrate, a temperature sensing diode formed on the semiconductor substrate, an anode wiring connected to an anode portion of the temperature sensing diode, and a cathode wiring connected to a cathode portion of the temperature sensing diode. One of the anode wiring and the cathode wiring is disposed so as to overlap the other.

According to the semiconductor device of the present disclosure, an area of the wiring between the temperature sensing diode and the temperature sense terminal can be reduced.

These and other objects, features, aspects and advantages of the present disclosure will become more apparent from the following detailed description of the present disclosure when taken in conjunction with the accompanying drawings.

### BRIEF DESCRIPTION OF DRAWINGS

FIG. 1 is a cross-sectional view of a temperature sensing diode included in a semiconductor device according to a first preferred embodiment;

FIG. 2 is a view illustrating a modification of the temperature sensing diode included in the semiconductor device according to the first preferred embodiment;

FIG. 3 is a cross-sectional view of a temperature sensing diode included in a semiconductor device according to a second preferred embodiment;

FIG. 4 is a view illustrating a modification of the temperature sensing diode included in the semiconductor device according to the second preferred embodiment;

FIG. 5 is a cross-sectional view of a temperature sensing diode included in a semiconductor device according to a third preferred embodiment;

FIG. 6 is a view illustrating a modification of the temperature sensing diode included in the semiconductor device according to the third preferred embodiment;

FIG. 7 is a cross-sectional view of a temperature sensing diode included in a semiconductor device according to a fourth preferred embodiment;

FIG. 8 is a view illustrating a modification of the temperature sensing diode included in the semiconductor device according to the fourth preferred embodiment;

FIG. 9 is a cross-sectional view of a temperature sensing diode included in a semiconductor device according to a fifth preferred embodiment;

FIG. 10 is a view illustrating a modification of the temperature sensing diode included in the semiconductor device according to the fifth preferred embodiment;

FIG. 11 is a cross-sectional view of a temperature sensing diode included in a semiconductor device according to a sixth preferred embodiment; and

FIG. 12 is a view illustrating a modification of the temperature sensing diode included in the semiconductor device according to the sixth preferred embodiment.

### DESCRIPTION OF THE PREFERRED EMBODIMENTS

### <first Preferred Embodiment>

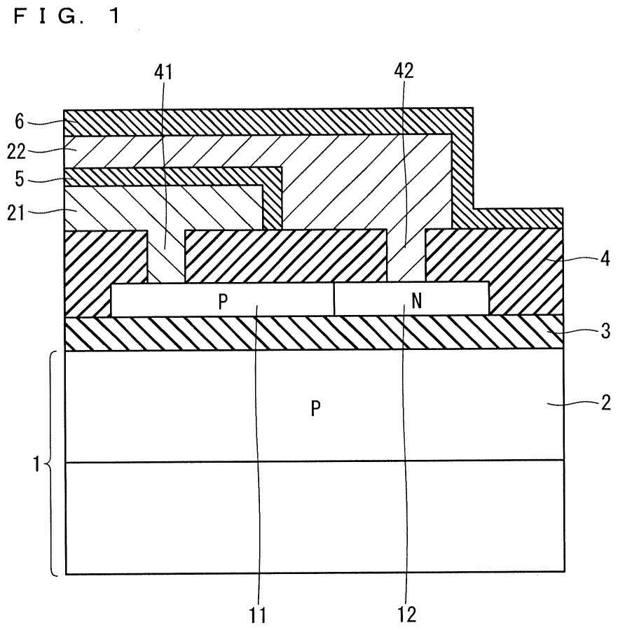

FIG. 1 is a cross-sectional view of a temperature sensing diode included in a semiconductor device according to a first preferred embodiment. It is assumed that the temperature sensing diode is disposed in a central portion of an active region of a

### Semiconductor Substrate 1.

Although not illustrated, a semiconductor element such as a metal oxide semiconductor field effect transistor (MOSFET) or an insulated gate bipolar transistor (IGBT) is formed in the active region of the semiconductor substrate 1. There is no restriction on the type of the semiconductor element to be formed in the active region. In addition, the semiconductor substrate 1 may be made of silicon (Si), or may be made of a wide band gap semiconductor such as silicon carbide (SiC) or gallium nitride (GnN), for example. A semiconductor device formed using a wide band gap semiconductor is excellent in operation at high voltage, large current, and high temperature as compared with a semiconductor device using silicon in related art.

In FIG. 1, the temperature sensing diode is a PN junction diode that includes an anode portion 11 including a P-type semiconductor layer and a cathode portion 12 including an N-type semiconductor layer. The anode portion 11 and the cathode portion 12 are disposed on a first insulating film 3 formed on the semiconductor substrate 1. As a semiconductor layer constituting the anode portion 11 and the cathode portion 12, for example, polysilicon can be used.

An impurity layer 2 for suppressing concentration of an electric field is provided in a surface portion of the semiconductor substrate 1 under the temperature sensing diode. Hereinafter, the impurity layer 2 provided under the temperature sensing diode will be referred to as an “under-diode impurity layer 2”. Here, a conductivity type of the under-diode impurity layer 2 is P-type, but may be N-type.

A second insulating film 4 is formed on the anode portion 11 and the cathode portion 12. In the second insulating film 4, an anode wiring 21 to be connected to the anode portion 11 and a cathode wiring 22 to be connected to the cathode portion 12 are formed. The anode wiring 21 is connected to the anode portion 11 through an anode contact hole 41 formed in the second insulating film 4, and the cathode wiring 22 is connected to the cathode portion 12 through a cathode contact hole 42 formed in the second insulating film 4. The anode wiring 21 and the cathode wiring 22 are wirings for connecting the temperature sensing diode and a temperature sense terminal disposed outside the active region. In the present preferred embodiment, each of the anode wiring 21 and the cathode wiring 22 is a metal wiring including a metal layer.

As illustrated in FIG. 1, the anode wiring 21 is covered with a third insulating film 5, and the cathode wiring 22 is disposed on the third insulating film 5. In other words, the cathode wiring 22 is disposed to overlap the anode wiring 21, and the anode wiring 21 and the cathode wiring 22 are insulated by the third insulating film 5. In addition, the cathode wiring 22 is covered with a protective film 6.

According to the semiconductor device of the first preferred embodiment, the anode wiring 21 and the cathode wiring 22 form a stacked structure, and thus, an area of a region where the anode wiring 21 and the cathode wiring 22 are disposed can be reduced. This makes it possible to secure a wide effective area of the active region.

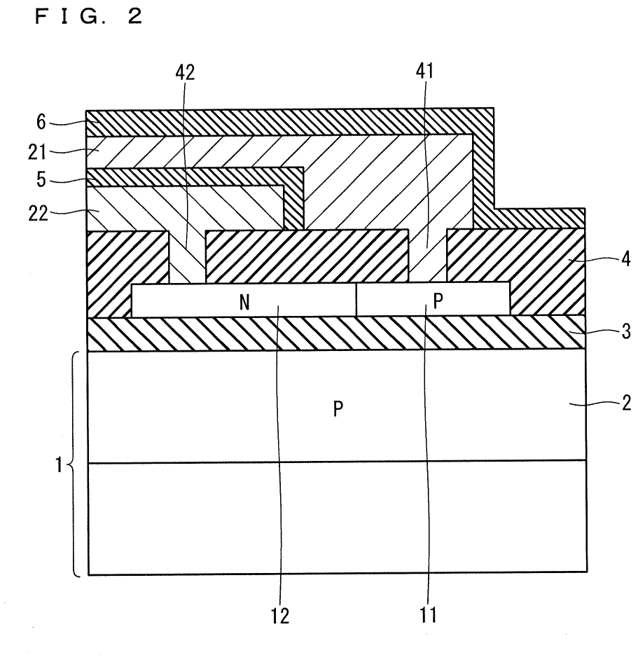

FIG. 1 illustrates an example in which the cathode wiring 22 is disposed to overlap the anode wiring 21, but the vertical relationship may be reversed. In other words, as illustrated in FIG. 2, the anode wiring 21 may be disposed to overlap the cathode wiring 22. In the configuration of FIG. 2, the anode portion 11 (P-type semiconductor layer) and the cathode portion 12 (N-type semiconductor layer) are interchanged with each other, and the anode wiring 21 and the cathode wiring 22 are interchanged with each other as compared with FIG. 1. Also in this structure, the area of the region where the anode wiring 21 and the cathode wiring 22 are disposed can be reduced.

As described above, either the anode wiring 21 or the cathode wiring 22 may be on the upper side. In other words, one of the anode wiring 21 and the cathode wiring 22 may be disposed to overlap the other.

<Second preferred embodiment>

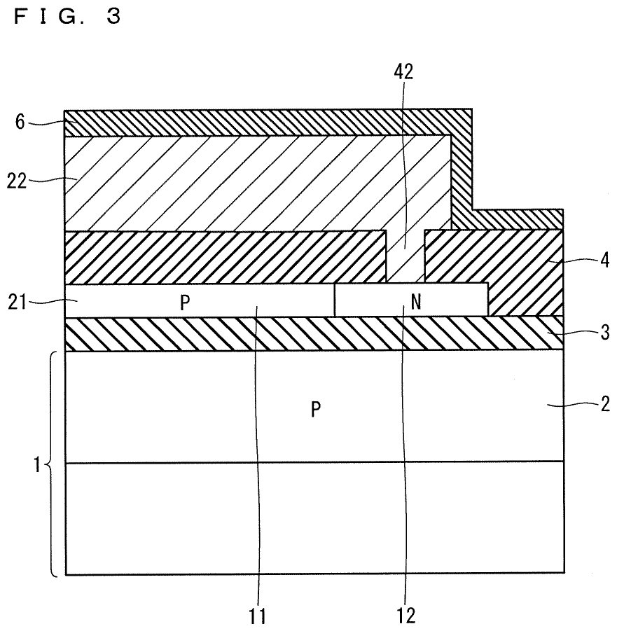

FIG. 3 is a cross-sectional view of a temperature sensing diode included in a semiconductor device according to a second preferred embodiment. As illustrated in FIG. 3, in the semiconductor device according to the second preferred embodiment, the anode wiring 21 connected to the anode portion 11 of the temperature sensing diode includes the same P-type semiconductor layer as the anode portion 11. Similarly to FIG. 1, the cathode wiring 22 includes a metal layer formed on the second insulating film 4, and is connected to the cathode portion 12 through the cathode contact hole 42. In this configuration, the anode wiring 21 and the cathode wiring 22 are insulated by the second insulating film 4, and thus, the third insulating film 5 illustrated in FIG. 1 can be omitted.

Also in the second preferred embodiment, the cathode wiring 22 is disposed to overlap the anode wiring 21. Thus, as in the first preferred embodiment, the area of the region where the anode wiring 21 and the cathode wiring 22 are disposed can be reduced. In addition, the number of metal layers formed on the second insulating film 4 is smaller than that in the first preferred embodiment, which can contribute to reduction in the number of manufacturing steps.

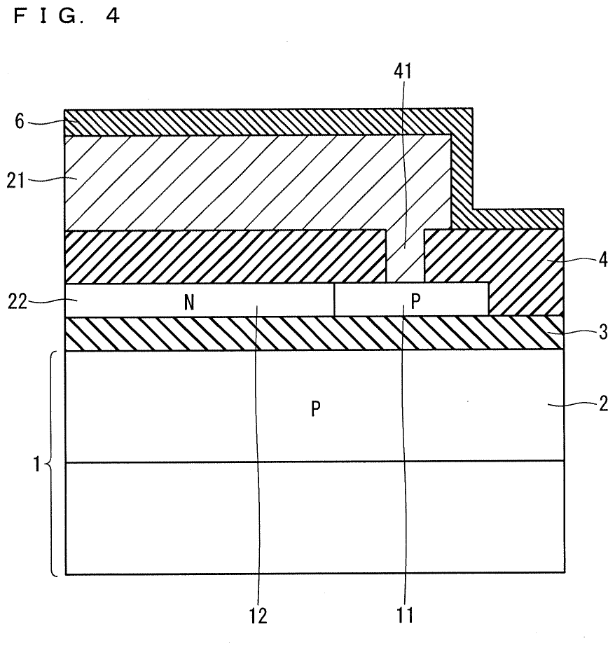

FIG. 3 illustrates an example in which the cathode wiring 22 is disposed to overlap the anode wiring 21, but the vertical relationship may be reversed. In other words, as illustrated in FIG. 4, the cathode wiring 22 may include the same N-type semiconductor layer as the cathode portion 12, and the anode wiring 21 may include a metal layer formed on the second insulating film 4 and connected to the anode portion 11 through the anode contact hole 41. In the configuration of FIG. 4, the anode portion 11 and the cathode portion 12 are interchanged with each other, and the anode wiring 21 and the cathode wiring 22 are interchanged with each other as compared with FIG. 3. Also in this structure, the area of the region where the anode wiring 21 and the cathode wiring 22 are disposed can be reduced.

As described above, either the anode wiring 21 or the cathode wiring 22 may be on the upper side. In other words, one of the anode wiring 21 and the cathode wiring 22 may be disposed to overlap the other.

<Third preferred embodiment>

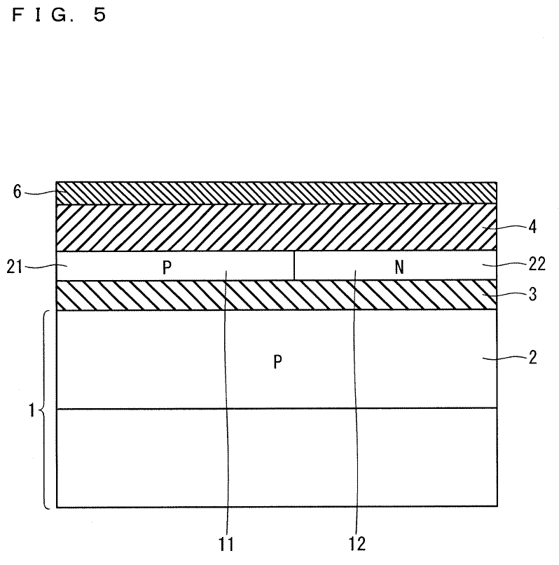

FIG. 5 is a cross-sectional view of a temperature sensing diode included in a semiconductor device according to a third preferred embodiment. As illustrated in FIG. 5, in the third preferred embodiment, the anode wiring 21 connected to the anode portion 11 of the temperature sensing diode includes the same P-type semiconductor layer as the anode portion 11, and the cathode wiring 22 connected to the cathode portion 12 of the temperature sensing diode includes the same N-type semiconductor layer as the cathode portion 12. It is therefore not necessary to form a metal layer for the anode wiring 21 and the cathode wiring 22 on the second insulating film 4.

For example, the semiconductor layer such as polysilicon can be processed to have a width narrower than that of the metal layer. Thus, in the third preferred embodiment, the area of the region where the anode wiring 21 and the cathode wiring 22 are disposed can be reduced by making the anode wiring 21 and the cathode wiring 22 thinner. In addition, it is not necessary to provide a metal layer on the second insulating film 4, which can contribute to reduction in the number of manufacturing steps.

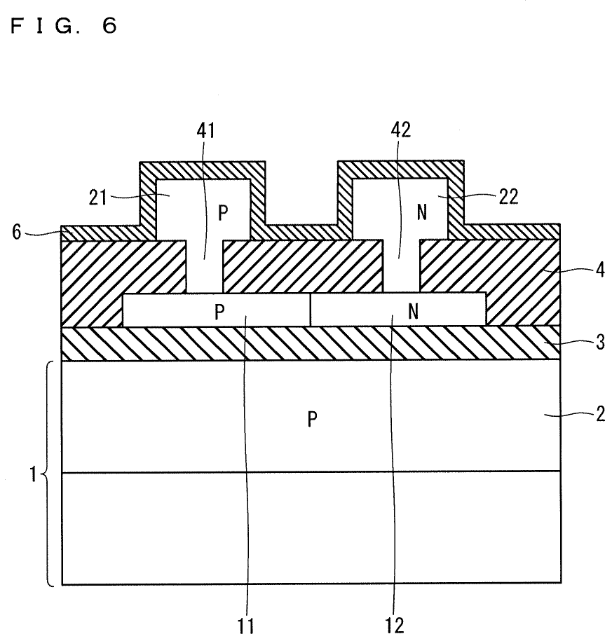

In FIG. 5, the anode wiring 21 includes the same P-type semiconductor layer as the anode portion 11, but the anode wiring 21 may be a P-type semiconductor layer different from the anode portion 11. Similarly, in FIG. 5, the cathode wiring 22 includes the same N-type semiconductor layer as the cathode portion 12, but the cathode wiring 22 may be an N-type semiconductor layer different from the cathode portion 12. For example, as illustrated in FIG. 6, the anode wiring 21 including the P-type semiconductor layer and the cathode wiring 22 including the N-type semiconductor layer may be disposed on the second insulating film 4. The anode wiring 21 is connected to the anode portion 11 through the anode contact hole 41 formed in the second insulating film 4, and the cathode wiring 22 is connected to the cathode portion 12 through the cathode contact hole 42. In FIG. 6, the anode wiring 21 and the cathode wiring 22 extend in a depth direction of the paper surface. Also in the configuration of FIG. 6, the area of the region where the anode wiring 21 and the cathode wiring 22 are disposed can be reduced by making the anode wiring 21 and the cathode wiring 22 thinner.

In a case where at least one of the anode wiring 21 including the P-type semiconductor layer and the cathode wiring 22 including the N-type semiconductor layer is disposed on the second insulating film 4, one of the anode wiring 21 and the cathode wiring 22 may be disposed to overlap the other as in the first or the second preferred embodiment (FIGS. 1 to 4). In other words, the anode wiring 21 may be changed to the P-type semiconductor layer, and the cathode wiring 22 may be changed to the N-type semiconductor layer, in the configurations of FIGS. 1 to 4. The area of the region where the anode wiring 21 and the cathode wiring 22 are disposed can be reduced compared to the first and second preferred embodiments by an amount corresponding to the anode wiring 21 and the cathode wiring 22 being made thinner.

From the viewpoint of reducing resistance of the anode wiring 21 and the cathode wiring 22, an impurity concentration of the P-type semiconductor layer constituting the anode wiring 21 and the N-type semiconductor layer constituting the cathode wiring 22 is preferably higher than an impurity concentration of the under-diode impurity layer 2.

<Fourth preferred embodiment>

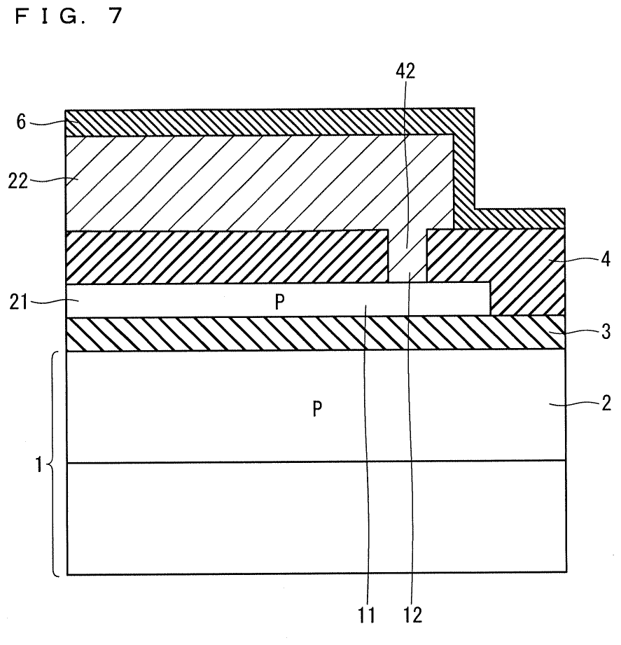

FIG. 7 is a cross-sectional view of a temperature sensing diode included in a semiconductor device according to a fourth preferred embodiment. In the configuration of FIG. 7, the N-type semiconductor layer as the cathode portion 12 in FIG. 3 is replaced with the P-type semiconductor layer as the anode portion 11.

The anode portion 11 extends below the cathode contact hole 42, and the metal layer constituting the cathode wiring 22 is connected to the anode wiring 21 through the cathode contact hole 42. In this event, the metal layer in the cathode contact hole 42 forms a Schottky junction with the P-type semiconductor layer as the anode portion 11 and functions as the cathode portion 12. In other words, the temperature sensing diode of the present preferred embodiment is a Schottky barrier diode that includes the anode portion 11 including the P-type semiconductor layer and the cathode portion 12 including the metal layer.

The anode wiring 21 includes the same P-type semiconductor layer as the anode portion 11. The cathode wiring 22 includes the metal layer formed on the second insulating film 4, and a portion thereof (a portion in the cathode contact hole 42) serves as the cathode portion 12.

Also in the fourth preferred embodiment, the cathode wiring 22 is disposed to overlap the anode wiring 21. Thus, as in the first preferred embodiment, the area of the region where the anode wiring 21 and the cathode wiring 22 are disposed can be reduced. In addition, the Schottky barrier diode has better responsiveness to a temperature than the PN junction diode, and thus, an effect that the temperature of the semiconductor element can be monitored with higher sensitivity than in the first to the third preferred embodiments can be obtained.

In the fourth preferred embodiment, the metal layer to be the cathode portion 12 (the metal layer in the cathode contact hole 42) needs to have characteristics of a Schottky junction with the P-type semiconductor layer of the anode portion 11. On the other hand, there is no such restriction on the metal layer to be the cathode wiring 22 (the metal layer on the second insulating film 4). Thus, the cathode portion 12 and the cathode wiring 22 may include different metals. In other words, the cathode wiring 22 may include another metal layer connected to the metal layer of the cathode portion 12.

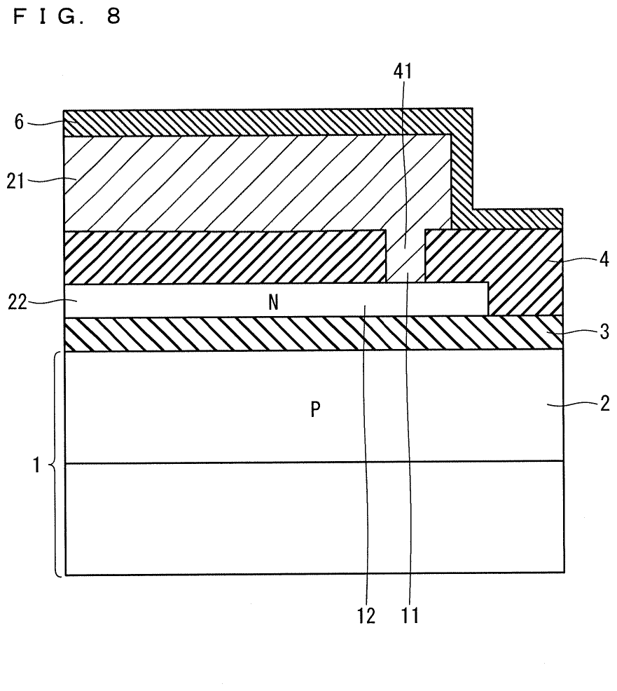

FIG. 7 illustrates a Schottky barrier diode in which the anode portion 11 includes the P-type semiconductor layer below the second insulating film 4, and the cathode portion 12 includes the metal layer above the second insulating film 4. Conversely, as illustrated in FIG. 8, the anode portion 11 may include the metal layer above the second insulating film 4, and the cathode portion 12 may include the N-type semiconductor layer below the second insulating film 4. In the configuration of FIG. 8, the P-type semiconductor layer as the anode portion 11 in FIG. 4 is replaced with the N-type semiconductor layer as the cathode portion 12.

The anode wiring 21 includes the metal layer formed on the second insulating film 4, and a portion thereof (a portion in the anode contact hole 41) of the anode wiring becomes the anode portion 11. The cathode wiring 22 includes the same N-type semiconductor layer as the cathode portion 12. The anode wiring 21 is disposed to overlap the cathode wiring 22. Also in this structure, the area of the region where the anode wiring 21 and the cathode wiring 22 are disposed can be reduced.

As described above, either the anode wiring 21 or the cathode wiring 22 may be on the upper side. In other words, one of the anode wiring 21 and the cathode wiring 22 may be disposed to overlap the other.

In the configuration of FIG. 8, the metal layer to be the anode portion 11 (the metal layer in the anode contact hole 41) needs to have characteristics of a Schottky junction with the N-type semiconductor layer of the cathode portion 12. On the other hand, there is no such restriction on the metal layer to be the anode wiring 21 (the metal layer on the second insulating film 4). Thus, the anode portion 11 and the anode wiring 21 may include different metals. In other words, the anode wiring 21 may include another metal layer connected to the metal layer of the anode portion 11.

<Fifth preferred embodiment>

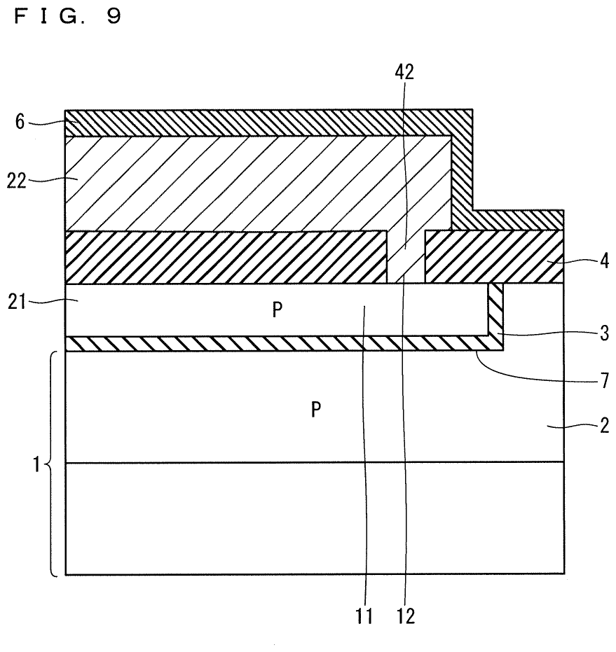

FIG. 9 is a cross-sectional view of a temperature sensing diode included in a semiconductor device according to a fifth preferred embodiment. In the configuration of FIG. 9, the first insulating film 3 of FIG. 7 and the P-type semiconductor layer as the anode portion 11 and the anode wiring 21 are disposed in a trench 7 formed in the semiconductor substrate 1.

Also in FIG. 9, as in FIG. 7, the temperature sensing diode is a Schottky barrier diode that includes the anode portion 11 including the P-type semiconductor layer and the cathode portion 12 including the metal layer. The anode wiring 21 includes the same P-type semiconductor layer as the anode portion 11. The cathode wiring 22 includes the metal layer formed on the second insulating film 4, and a portion thereof (a portion in the cathode contact hole 42) serves as the cathode portion 12.

Also in the fifth preferred embodiment, the cathode wiring 22 is disposed to overlap the anode wiring 21. Thus, as in the first preferred embodiment, the area of the region where the anode wiring 21 and the cathode wiring 22 are disposed can be reduced. In addition, the temperature sensing diode is embedded in the trench 7, and thus, heat generated in the semiconductor element is easily transferred to the temperature sensing diode, so that it is possible to obtain an effect that the temperature of the semiconductor element can be monitored with higher sensitivity than in the fourth preferred embodiment.

Also in the fifth preferred embodiment, the metal layer to be the cathode portion 12 (the metal layer in the cathode contact hole 42) and the metal layer to be the cathode wiring 22 (the metal layer on the second insulating film 4) may include different metals. In other words, the cathode wiring 22 may include another metal layer connected to the metal layer of the cathode portion 12.

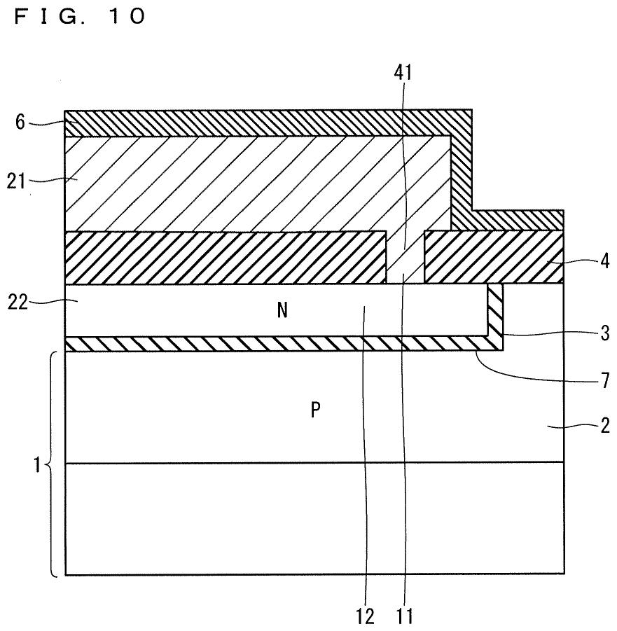

FIG. 9 illustrates a Schottky barrier diode in which the anode portion 11 includes the P-type semiconductor layer below the second insulating film 4, and the cathode portion 12 includes the metal layer above the second insulating film 4. Conversely, as illustrated in FIG. 10, the anode portion 11 may include the metal layer above the second insulating film 4, and the cathode portion 12 may include the N-type semiconductor layer below the second insulating film 4. In the configuration of FIG. 10, the first insulating film 3 of FIG. 8 and the N-type semiconductor layer as the cathode portion 12 and the cathode wiring 22 are disposed in the trench 7 formed in the semiconductor substrate 1.

The anode wiring 21 includes the metal layer formed on the second insulating film 4, and a portion thereof (a portion in the anode contact hole 41) of the anode wiring becomes the anode portion 11. The cathode wiring 22 includes the same N-type semiconductor layer as the cathode portion 12. The anode wiring 21 is disposed to overlap the cathode wiring 22. Also in this structure, the area of the region where the anode wiring 21 and the cathode wiring 22 are disposed can be reduced.

As described above, either the anode wiring 21 or the cathode wiring 22 may be on the upper side. In other words, one of the anode wiring 21 and the cathode wiring 22 may be disposed to overlap the other.

Also in FIG. 10, the metal layer to be the anode portion 11 (the metal layer in the anode contact hole 41) and the metal layer to be the anode wiring 21 (the metal layer on the second insulating film 4) may include different metals. In other words, the anode wiring 21 may include another metal layer connected to the metal layer of the anode portion 11.

<Sixth preferred embodiment>

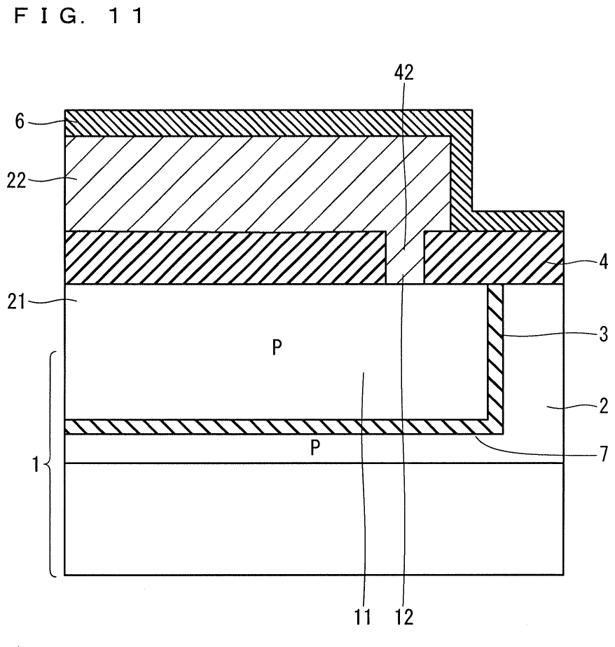

FIG. 11 is a cross-sectional view of a temperature sensing diode included in a semiconductor device according to a sixth preferred embodiment. The semiconductor device according to the sixth preferred embodiment includes a trench gate type semiconductor element (for example, a MOSFET, an IGBT, or the like) including a gate electrode embedded in a trench formed in the semiconductor substrate 1 in an active region not illustrated.

The configuration of FIG. 11 is basically the same as that of FIG. 7, but in the sixth preferred embodiment, the trench 7, the first insulating film 3, and the P-type semiconductor layer as the anode portion 11 and the anode wiring 21 are formed simultaneously with a formation step of the gate electrode of the semiconductor element. In other words, the trench 7 is formed simultaneously with the trench in which the gate electrode is embedded, the first insulating film 3 is formed simultaneously with the gate insulating film provided under the gate electrode, and the P-type semiconductor layer as the anode portion 11 and the anode wiring 21 is formed simultaneously with the gate electrode. Thus, in the present preferred embodiment, a depth of the trench 7 is the same as a depth of the trench in which the gate electrode is to be embedded, the first insulating film 3 includes the same insulating film as the gate insulating film, and the anode portion 11 and the anode wiring 21 include the same P-type semiconductor layer as the gate electrode of the semiconductor element.

In addition, the second insulating film 4 can be formed simultaneously with an interlayer insulating film that covers the gate electrode. The cathode wiring 22 can be formed simultaneously with an upper surface electrode (such as an emitter electrode and a source electrode) of the semiconductor element.

According to the present preferred embodiment, the temperature sensing diode (the anode portion 11 and the cathode portion 12), and the anode wiring 21 and the cathode wiring 22 connected thereto can be formed simultaneously with the semiconductor element in the active region, which can contribute to reduction of the number of manufacturing steps

### Of the Semiconductor Device.

Also in the sixth preferred embodiment, the cathode wiring 22 is disposed to overlap the anode wiring 21. Thus, as in the first preferred embodiment, the area of the region where the anode wiring 21 and the cathode wiring 22 are disposed can be reduced. In addition, the temperature sensing diode is embedded in the trench 7, and thus, heat generated in the semiconductor element is easily transferred to the temperature sensing diode, so that it is possible to obtain an effect that the temperature of the semiconductor element can be monitored with higher sensitivity than in the fourth preferred embodiment.

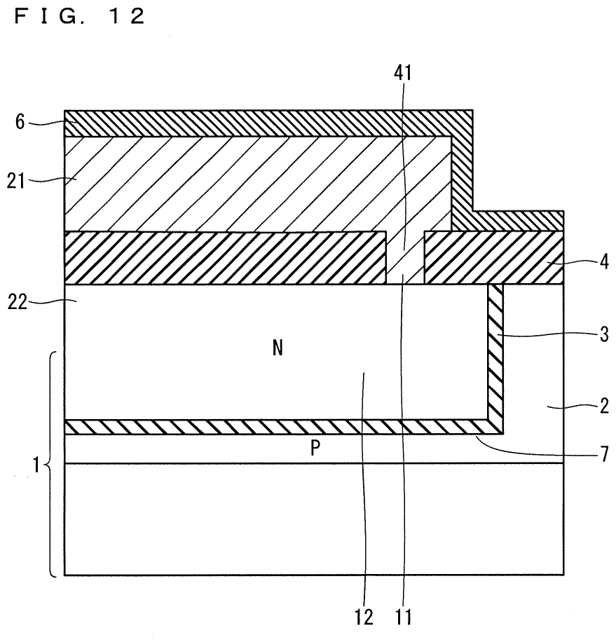

FIG. 11 illustrates a Schottky barrier diode in which the anode portion 11 includes the P-type semiconductor layer below the second insulating film 4, and the cathode portion 12 includes the metal layer above the second insulating film 4. Conversely, as illustrated in FIG. 12, the anode portion 11 may include the metal layer above the second insulating film 4, and the cathode portion 12 may include the N-type semiconductor layer below the second insulating film 4. The configuration of FIG. 12 is basically the same as that of FIG. 10, but the trench 7, the first insulating film 3, and the N-type semiconductor layer as the cathode portion 12 and the cathode wiring 22 are simultaneously formed in the step of forming the gate electrode of the semiconductor element. Accordingly, the cathode portion 12 and the cathode wiring 22 include the same N-type semiconductor layer as the gate electrode of the semiconductor element.

As described above, either the anode wiring 21 or the cathode wiring 22 may be on the upper side. In other words, one of the anode wiring 21 and the cathode wiring 22 may be disposed to overlap the other.

Note that the preferred embodiments can be freely combined, and the preferred embodiments can be appropriately modified or omitted.

<Appendices>

Hereinafter, various aspects of the present disclosure will be collectively described as appendices.

(Appendix 1)

A semiconductor device comprising:
a semiconductor substrate;
a temperature sensing diode formed on the semiconductor substrate;
an anode wiring connected to an anode portion of the temperature sensing diode; and

a cathode wiring connected to a cathode portion of the temperature sensing diode,

wherein one of the anode wiring and the cathode wiring is disposed so as to overlap the other.

### (appendix 2)

The semiconductor device according to Appendix 1, wherein the temperature sensing diode is a PN junction diode that includes the anode portion including a P-type semiconductor layer and the cathode portion including an N-type semiconductor layer.

(Appendix 3)

The semiconductor device according to Appendix 2, wherein

the anode wiring includes a metal layer connected to the anode portion, and

the cathode wiring includes a metal layer connected to the cathode portion.

(Appendix 4)

The semiconductor device according to Appendix 2, wherein

the anode wiring includes the same P-type semiconductor layer as the anode portion, and

the cathode wiring includes a metal layer connected to the cathode portion.

(Appendix 5)

The semiconductor device according to Appendix 2, wherein

the anode wiring includes a metal layer connected to the anode portion, and

the cathode wiring includes the same N-type semiconductor layer as the cathode portion.

(Appendix 6)

The semiconductor device according to Appendix 2, wherein each of the anode wiring and the cathode wiring includes a semiconductor layer.

(Appendix 7)

The semiconductor device according to Appendix 1, wherein the temperature sensing diode is a Schottky barrier diode that includes the anode portion including a P-type semiconductor layer and the cathode portion including a metal layer.

(Appendix 8)

The semiconductor device according to Appendix 7, wherein

the anode wiring includes the same P-type semiconductor layer as the anode portion, and

the cathode wiring includes the same metal layer as the cathode portion or another metal layer connected to the metal layer of the cathode portion.

(Appendix 9)

The semiconductor device according to Appendix 8, wherein the anode portion and the anode wiring are disposed in a trench formed in the semiconductor substrate.

(Appendix 10)

The semiconductor device according to Appendix 9, further comprising a semiconductor element including a gate electrode disposed in the trench formed in the semiconductor substrate,

wherein the anode portion includes the same P-type semiconductor layer as the gate electrode.

### (appendix 11)

The semiconductor device according to Appendix 1, wherein the temperature sensing diode is a Schottky barrier diode that includes the anode portion including a metal layer and the cathode portion including an N-type semiconductor layer.

(Appendix 12)

The semiconductor device according to Appendix 11, wherein

the anode wiring includes the same metal layer as the anode portion or another metal layer connected to the metal layer of the anode portion, and

the cathode wiring includes the same N-type semiconductor layer as the cathode portion.

(Appendix 13)

The semiconductor device according to Appendix 12, wherein the cathode portion and the cathode wiring are disposed in a trench formed in the semiconductor substrate.

### (appendix 14)

The semiconductor device according to Appendix 13, further comprising a semiconductor element including a gate electrode disposed in the trench formed in the semiconductor substrate,

wherein the gate electrode includes the same N-type semiconductor layer as the cathode portion.

(Appendix 15)

A semiconductor device comprising:
a semiconductor substrate;
a temperature sensing diode formed on the semiconductor substrate;
an anode wiring connected to an anode portion of the temperature sensing diode; and

a cathode wiring connected to a cathode portion of the temperature sensing diode,

wherein the temperature sensing diode is a PN junction diode that includes the anode portion including a P-type semiconductor layer and the cathode portion including an N-type semiconductor layer, and

each of the anode wiring and the cathode wiring includes a semiconductor layer.

(Appendix 16)

The semiconductor device according to the Appendix 15, wherein an impurity concentration of the semiconductor layer constituting the anode wiring and the cathode wiring is higher than an impurity concentration of an impurity layer formed in a surface portion of the semiconductor substrate under the temperature sensing diode.

(Appendix 17)

The semiconductor device according to Appendix 15, wherein

the semiconductor layer constituting the anode wiring is the same P-type semiconductor layer as the anode portion, and

the semiconductor layer constituting the cathode wiring is the same N-type semiconductor layer as the cathode portion.

While the disclosure has been shown and described in detail, the foregoing description is in all aspects illustrative and not restrictive. It is therefore understood that numerous modifications and variations can be devised.

What is claimed is:

1. A semiconductor device comprising:
a semiconductor substrate;
a temperature sensing diode formed on the semiconductor substrate;
an anode wiring connected to an anode portion of the temperature sensing diode;
and a cathode wiring connected to a cathode portion of the temperature sensing diode,
wherein one of the anode wiring and the cathode wiring is disposed so as to overlap the other.

2. The semiconductor device according to claim 1, wherein the temperature sensing diode is a PN junction diode that includes the anode portion including a P-type semiconductor layer and the cathode portion including an N-type semiconductor layer.

3. The semiconductor device according to claim 2, wherein the anode wiring includes a metal layer connected to the anode portion, and the cathode wiring includes a metal layer connected to the cathode portion.

4. The semiconductor device according to claim 2, wherein
the anode wiring includes the same P-type semiconductor layer as the anode portion, and
the cathode wiring includes a metal layer connected to the cathode portion.

5. The semiconductor device according to claim 2, wherein
the anode wiring includes a metal layer connected to the anode portion, and
the cathode wiring includes the same N-type semiconductor layer as the cathode portion.

6. The semiconductor device according to claim 2, wherein each of the anode wiring and the cathode wiring includes a semiconductor layer.

7. The semiconductor device according to claim 1, wherein the temperature sensing diode is a Schottky barrier diode that includes the anode portion including a P-type semiconductor layer and the cathode portion including a metal layer.

8. The semiconductor device according to claim 7, wherein
the anode wiring includes the same P-type semiconductor layer as the anode portion, and
the cathode wiring includes the same metal layer as the cathode portion or another metal layer connected to the metal layer of the cathode portion.

9. The semiconductor device according to claim 8, wherein the anode portion and the anode wiring are disposed in a trench formed in the semiconductor substrate.

10. The semiconductor device according to claim 9, further comprising a semiconductor element including a gate electrode disposed in the trench formed in the semiconductor substrate,
wherein the anode portion includes the same P-type semiconductor layer as the gate electrode.

11. The semiconductor device according to claim 1, wherein the temperature sensing diode is a Schottky barrier diode that includes the anode portion including a metal layer and the cathode portion including an N-type semiconductor layer.

12. The semiconductor device according to claim 11, wherein
the anode wiring includes the same metal layer as the anode portion or another metal layer connected to the metal layer of the anode portion, and
the cathode wiring includes the same N-type semiconductor layer as the cathode portion.

13. The semiconductor device according to claim 12, wherein the cathode portion and the cathode wiring are disposed in a trench formed in the semiconductor substrate.

14. The semiconductor device according to claim 13, further comprising a semiconductor element including a gate electrode disposed in the trench formed in the semiconductor substrate,
wherein the gate electrode includes the same N-type semiconductor layer as the cathode portion.

15. A semiconductor device comprising:
a semiconductor substrate;
a temperature sensing diode formed on the semiconductor substrate;
an anode wiring connected to an anode portion of the temperature sensing diode;
and a cathode wiring connected to a cathode portion of the temperature sensing diode,
wherein the temperature sensing diode is a PN junction diode that includes the anode portion including a P-type semiconductor layer and the cathode portion including an N-type semiconductor layer, and
each of the anode wiring and the cathode wiring includes a semiconductor layer.

16. The semiconductor device according to claim 15, wherein an impurity concentration of the semiconductor layer constituting the anode wiring and the cathode wiring is higher than an impurity concentration of an impurity layer formed in a surface portion of the semiconductor substrate under the temperature sensing diode.

17. The semiconductor device according to claim 15, wherein
the semiconductor layer constituting the anode wiring is the same P-type semiconductor layer as the anode portion, and
the semiconductor layer constituting the cathode wiring is the same N-type semiconductor layer as the cathode portion.
